(19) United States
(12) Patent Application Publication
(10) Pub. No.: US 2018/0331571 A1
(43) Pub. Date: Nov. 15, 2018

(54) SYSTEM FOR MONITORING ELECTRIC CURRENT IN A NETWORK, AND ELECTRICAL FUSE THEREOF

(71) Applicant: Alliander N.V., Arnhen (NL)

(72) Inventor: Gerrit SMIT, Duiven (NL)

(21) Appl. No.: 15/773,886

(22) PCT Filed: Nov. 4, 2016
(86) PCT No.: PCT/NL2016/050766

§ 371 Date: May 4, 2018

(30) Foreign Application Priority Data
Nov. 6, 2015 (NL) 2015736

(51) Int. Cl. H02J 13/00; G01R 15/18; G01R 15/20; H01H 9/16; H01H 85/30

(52) U.S. Cl. CPC H02J 13/0013; G01R 15/181; H01H 85/30; H01H 9/167; G01R 15/202

(57) ABSTRACT

A system for monitoring electric current in a network comprising at least one electrical fuse including a protective body, and at least one interrogating device arranged to interrogate at least one current sensing unit. The invention also concerns a method to monitor electric current in a network, including the steps of: determining a current in the electrical fuse, for example, via a voltage drop measurement across a fusible resistor in the electrical fuse; transmitting current determinations from the current sensing unit, for example, to a central management device; and processing received data from the at least one current sensing unit.

The invention relates to a system for monitoring electric current in a network comprising at least one electrical fuse including a protective body, and at least one interrogating device arranged to interrogate at least one current sensing unit.

Such systems are generally known from prior art, for example from DE 10 2004 002 360, disclosing an electric fuse with two current connections, in between which a fuse and a resistor or shunt are placed in series. Two measuring connections allow a measuring device to be connected in order to measure the voltage drop across the resistor or shunt. The fuse can include a memory to store calibration data of the resistor.

Another example of a prior art system is disclosed in DE 10 2011 083 826 showing a resistor or shunt for an electric circuit in the shape of an electric fuse.

These prior art systems reveal several problems. Both systems need an external voltmeter to be connected in order to measure a voltage drop across the resistor, implying multiple wired connections to be effected. They are also arranged to be implemented only in case of necessity, for example to find a failure in the circuit or the network.

Prior art document WO2013/022578 discloses systems methods for housing electronics in an automobile, the system comprises a set of electronic components and a connector configured to be attached to the set of electronic components, the connector being configured to connect to an automotive fuse box. In an embodiment, a device is configured to replicate the functionality of a traditional fuse in addition to performing any additional functionality that device may have. For example, the device may be configured to monitor current flowing through device and to open the circuit when the current exceeds a threshold value. This “fuse” functionality may be implemented using electronic components or, in alternative embodiments, the device may incorporate a traditional fuse circuit to perform the fuse functionality in addition to comprising the additional electronic components for implementing the additional functionality.

Prior art document US2008/231410 relates to electrical fuse indicators, used to detect when fuses enter an open state. Each fuse in an electrical system may be connected to a wireless identification element, which alerts a communication unit that the fuse has entered an open state. The wireless identification device may include an antenna. The antenna may be in contact with a fuse element, such that opening of the fuse element renders the antenna inoperable. Alternatively the antenna may be connected to the fuse element in such a manner that opening of the fuse element alters the frequency on which the antenna transmits. A logic port may also be used to detect the operational state of a fuse. Use of such indicators is compatible with existing infrastructure, according to US'410.

Similarly, prior art document WO2008/092469 discloses a fuse having at least one transponder which is designed to transmit a signal readable via radio. The fuse is designed to act on the transponder in such a way that when the fuse is tripped, said transponder can no longer send a signal readable via radio or a modified signal readable via radio.

EP1179827 relates to electrical apparatuses such as switches or circuit breakers comprising auxiliary circuits to give a remote indication of the states of said apparatuses.

It is an aim of the present invention to solve or alleviate one or more of the above-mentioned problems. Particularly, the invention aims at providing a more efficient system for monitoring electric current in a network in that the system can be used in a pro-active manner, allowing a substantial cost reduction. Furthermore, the invention aims at providing a system which is easy to install, reducing or even avoiding extra costs generated by the training of electricians.

To this aim, there is provided a system characterized by the features of claim 1.

As a current sensing unit is integrated within the protective body of a fuse, the installation of a system according to the present invention, apart from providing a separate and remotely placed interrogating device, merely requires the exchange of a standard fuse with the fuse including the integrated current sensing unit. The exchange of fuses is a known procedure for a person skilled in the art, and does not require additional training.

Furthermore, by replacing all, or at least part of all, fuses in a network or a circuit by fuses with an integrated current sensing unit, and by installing a current sensing unit interrogating device (for collecting current data from the current sensing unit), the network or circuit can be monitored continuously, which yields valuable information, for example on over- or under-dimensioned points of the network, to optimize the network or circuit and prevent possible failures.

Herein, the monitoring of the network (and respective instantaneous non-zero electrical current or currents) is particularly carried out during normal network operation, during e.g. end-users dissipating the respective electric power provided by the network (i.e. during the operational state wherein the fuse or fuses are conducting respective current or currents that are being fed to such end-users). A respective fuse can continuously measure respective (non-zero) current, wherein the resulting current measurements can be e.g. processed centrally for network optimization. Herein it will be clear that a fuse's current measurement can be expressed in various units of measurement, e.g. ampere, voltage, a measurement value, data, or differently (e.g. in International System units or in alternative units), as will be appreciated by the skilled person.

In particular, the current sensing unit is configured to detect or measure an instantaneous (non-zero, actual) current (ampere), running through the respective fuse, during normal fuse operation (i.e. when the fuse operates to conduct a non-zero current in the respective electricity network).

In an advantageous embodiment, the current sensing unit is arranged to deduce a current measurement from a sensing of a current induced magnetic field, wherein the current sensing unit comprises for example a Rogowski coil, or for example a Hall effect sensor. A Rogowski coil provides a highly linear current measurement and usually does not need temperature calibration.

In an alternative embodiment, the current sensing unit comprises a sensor, e.g. a voltmeter, arranged to measure a voltage drop, e.g. across a resistor of the fuse. From the voltage drop and the known resistance of the resistor, the current can then easily be derived, e.g. according to Ohm's law.

In a more preferred embodiment, the resistor across which a voltage drop is measured, is a fusible resistor of the fuse, the resistor being configured to provide overcurrent protection. As the fuse itself comprises a low resistance resistor, there is no need for a supplementary resistor placed in series with the fusible resistor of the fuse. Measurement of the voltage drop across the fusible resistor of the fuse simplifies the system.

It is advantageous that the current sensing unit comprises a data memory arranged to store the current sensing unit's measurements. It allows the interrogating device to interrogate the current sensing unit to receive the stored data, e.g. periodically, while it can still collect a complete set of measurements taken between two moments of interrogation.

It is still more advantageous that the current sensing unit comprises a control unit, for example a microcontroller or a microprocessor, to control a functioning of the current sensing unit. The control unit, for example the microcontroller or microprocessor, can for example control the current sensing unit's measurements, the storage of measurement data, and/or interrogation by the interrogating device. A microprocessor can also derive other physical current properties from the current sensing unit's measurements, for example mean current over a period of time, and/or other quantities. In this way, the entire processing, from the current measurement, for example via a voltage drop measurement, until transmission of an answer, for example to an interrogation by the interrogating device, can be controlled from within the protective body of the fuse.

It is preferred that the current sensing unit is configured to transmit, for example upon interrogation by the interrogating device, a wireless signal containing measurement results, or results derived therefrom, from the current sensing unit to the interrogating device, the current sensing unit preferably including a transmitter to transmit such information. An important advantage of a wireless communication between the current sensing unit and the interrogating device is the absence of wires to be connected upon installation of the system, which simplifies, and thus speeds up, installation, improves the safety of the place where the system is applied, and reduces installation costs.

It is still more preferred that the current sensing unit includes RFID (Radio Frequency Identification Device) transmission means, for example a sensor enabled RFID tag including an RFID code, and wherein the interrogating device is configured to wirelessly interrogate the RFID transmission means of the current sensing unit. The sensor enabled RFID tag may be configured to operate in the passive mode, which does not need power supply and only transmits as an answer to an interrogating signal. The sensor enabled RFID tag may also be configured to operate in a semi-passive or active mode requiring a power supply. The RFID communication between the RFID transmission means of the current sensing unit and the interrogating device can operate for example in the class 1 generation 2 mode UHF band around 868 Mhz, and can bridge a distance between the transmitter and the interrogating device of for example 5 m or more. Standardized RFID transmission technology means offer the possibility of continuous wireless transmission or communication between the current sensing unit and the interrogating device while needing less power than other standardized wireless technologies as for example ULE (Ultra Low Power DECT), Zigbee, Bluetooth, or wifi. Another alternative is SAW (Surface Acoustic Wave) technology, wherein the (analogue) transmitter does not need a power supply, but can only be read at very short distances. An additional advantage of RFID transmission technology means is the possibility to identify a unit equipped with an RFID tag.

In an advantageous embodiment the current sensing unit may comprise an energy harvesting means, for example a coil, arranged to provide the current sensing unit with energy to operate. This is a more long-lasting solution than the integration of a battery as a power supply needing regular replacement, thus reducing the total cost of ownership of the system. At the same time, an energy harvesting means, for example a coil, takes little space.

In a preferred embodiment, the electrical fuse in the system can be a blade type fuse, for example a standardized NH-type fuse, for example a standardized NH DIN 2 fuse. The standard for low-voltage power fuses is described in the IEC 60269 standard, or in the UL 248 for North America. NH-type fuses are commonly present in distribution transformer end stations, where a voltage is transformed from a transmission voltage, for example medium voltage, to a voltage adapted for household appliances, for example 110 V or 230 V, or may also be present in main switch rooms of large buildings or industrial plants. Other fuse types, for example diazed or neozed types or other types, are also possible.

In a highly advantageous embodiment, the system may further comprise a remote central management device communicatively connected via a communication link to at least one interrogating device, wherein the central management device is arranged to store and process data received from the at least one interrogating device. The communication link may be a wireless communication link or a wired link, for example a glass fibre or copper-wired link. The system may also comprise a data aggregator or concentrator device connected to the interrogating device and arranged to collect and temporarily store measurement results, an RFID code or other information received via the interrogating device from the current sensing unit until these results have been transmitted to the central management device, for example once a day or more or less often. The communication link may then also be configured to immediately transmit measurement results, for example in combination with an alarm signal, to the central management device if they exceed predetermined values. In this way, pro-active network supervision and control can be effected, and decisions based on this supervision can be taken before possible problems occur.

According to another aspect of the invention, there is provided an electrical fuse characterized by the features of claim 12. Such an electrical fuse can provide the above-mentioned advantages.

A further aspect of the invention provides a method to monitor electric current in a network characterized by the features of claim 18, leading to one or more of the above-mentioned advantages.

Yet another aspect of the invention provides an electric power distribution network characterized by the features of claim 19. The network can provide one or more of the above-mentioned advantages.

Depending claims provide further advantageous embodiments.

The present invention will be further elucidated with reference to figures of exemplary embodiments. Therein, corresponding elements are designated with corresponding reference signs.

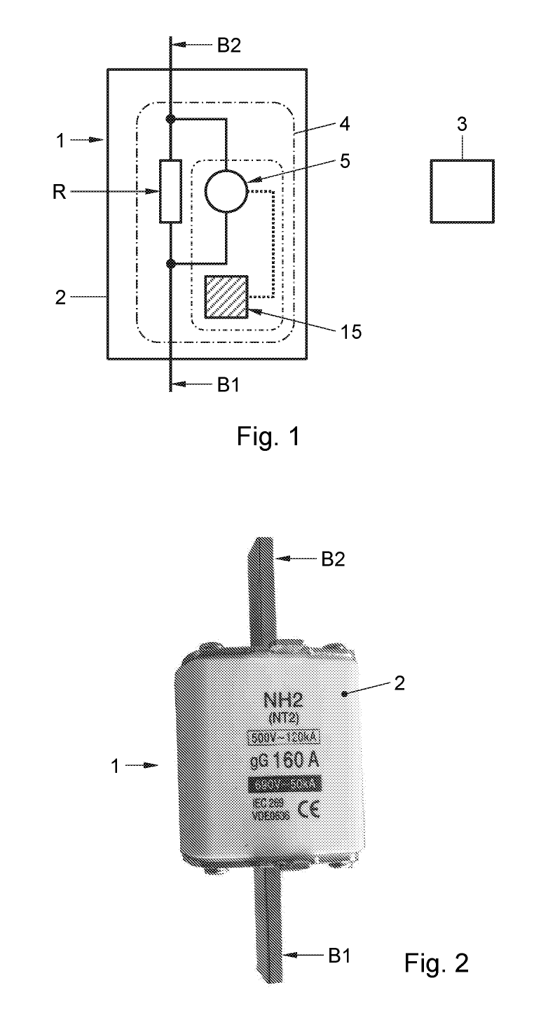

FIG. 1 shows a schematic representation of a system according to a first embodiment of the invention;

FIG. 2 shows a preferred embodiment of an electrical fuse according to an aspect of the invention, in perspective view;

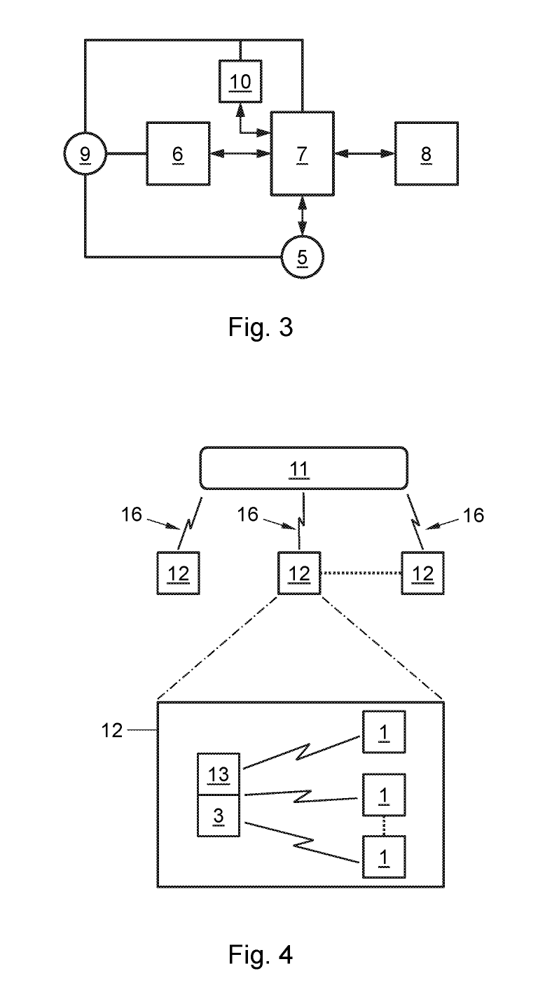

FIG. 3 shows a schematic and enlarged representation of a current sensing unit of the first embodiment of FIG. 1;

FIG. 4 shows a schematic representation of a second embodiment of a system according to the invention;

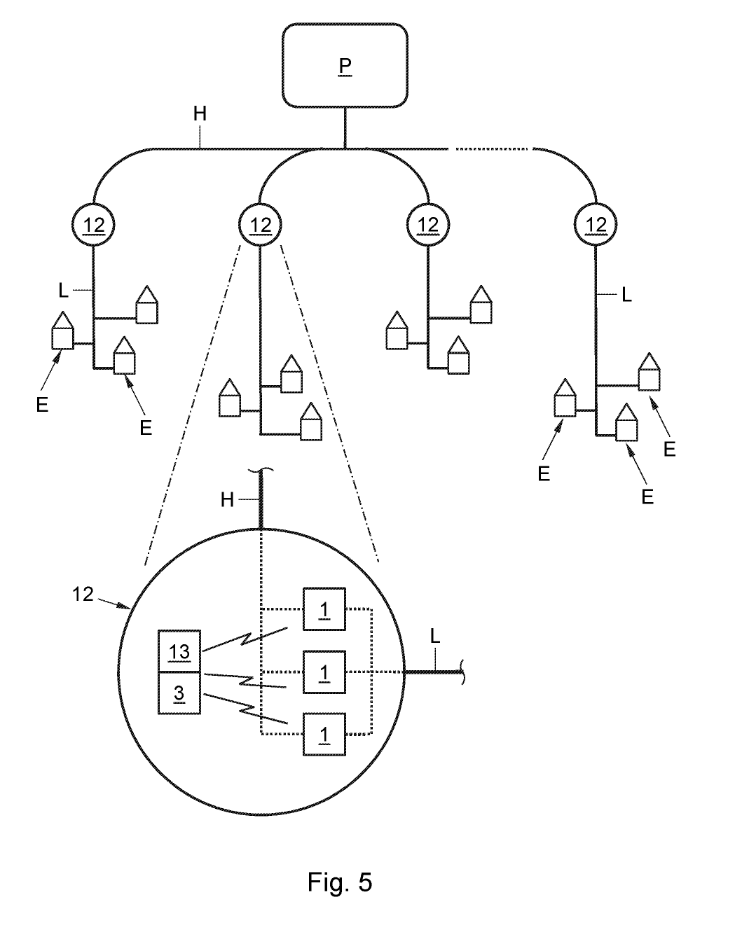

FIG. 5 shows a schematic representation of part of an electric power distribution network according to an aspect of the invention.

FIG. 1 shows a schematic representation of a system according to a first embodiment of the invention. The system for monitoring electric current in a network comprises at least one electrical fuse 1 including a protective body 2, and at least one separate and remotely placed interrogating device 3 arranged to interrogate at least one current sensing unit 4. The at least one fuse is integrated in an electricity network via two connections B1 and B2, for example blade-type connections. A blade B1, B2 can e.g. be a rigid electrically conducting flange, extending outwardly on top of the housing (see FIG. 2). Other connection styles, like screw type connections are also possible. The at least one fuse can for example be found in a distribution transformer end station, where a transmission voltage, for example medium voltage, is transformed into a lower voltage, e.g. adapted for household appliances. A set of standard voltages for use in low and high voltage AC electricity supply means is determined by the International Standard IEC 60038. According to this standard, a voltage of 50-1000 Vᵣₘₛ is considered to be low voltage, 1-35 kVᵣₘₛ is a medium voltage, and above 35 kV, a voltage can be a high, extra high or ultra high voltage. The electrical fuse can for example be a blade type fuse (see FIG. 2). The electric fuse comprises a fuse link, an element which is irreversibly blown if a current exceeds a given threshold current value, for example of, or more than, 250 A or another value.

As is mentioned before, a respective current sensing unit 4 can be configured to detect or measure an instantaneous (non-zero, actual) current (ampere), running through the fuse 1, and generate a respective current measurement result. In the preferred embodiment of FIG. 1, the current sensing unit 4 comprises a sensor 5 arranged to measure a voltage drop across a resistor R. The resistor R across which a voltage drop is measured, may be a fusible resistor of the fuse, which is the replaceable fuse link of the electric fuse. The fuse's resistor R can for example have a resistance of the order of 0.3 mΩ. With a current in a range of for example 1-250 A, a voltage drop in the range of 0.3-75 mV can be measured. A voltage drop could also be measured across a second resistor put in series with a fuse's resistor or differently. It follows that the current sensing unit measures the current, running through the fuse 1, during normal fuse operation when is it not blown or otherwise irreversibly degraded to a non-conducting state.

Alternatively, the current sensing unit 4 can be arranged to deduce a current measurement from a sensing of a current induced magnetic field, wherein the current sensing unit 4 may comprise for example a Rogowski coil, or for example a Hall effect sensor.

FIG. 2 shows a preferred embodiment of an electrical fuse according to an aspect of the invention. The electric fuse 1 in FIG. 2 is a standardized NH-type fuse, having a square or oblong body with blade-style terminals B1, B2, according to the IEC 60269 standard for low-voltage power fuses. NH-fuses have a larger current range than screw type fuses, up to for example 1.25 kA. For example, a standardized NH DIN 2 fuse has a current range of 125-400 A. Alternatively, the electric fuse can also be a standardized fuse according to the North-American UL 248 standard. The fuse 1 includes a protective body 2, in this case a square or oblong body enclosing the fusible resistor R. The fuse can be integrated in an electricity network via two connections B1 and B2, which can be blade-style terminals varying in length according to the fuse size between for example 70-200 mm, or approximately 150 mm for the standardized NH DIN2 type fuse. Preferably, the protective body 2 can be made entirely of for example ceramics and/or another type of protective material, the ceramics or other protective material completely enclosing the current sensing unit 4. Alternatively, parts of the current sensing unit, for example an antenna or a chip, or, in the most extreme case, the whole current sensing unit, may be integrated in the protective housing itself, thus forming part of the protective body. A ceramic part of the protective body (if any) and an electronics part 15, 5 of a current sensing unit in the protective body together can then either be thicker than a standardized size of, for example, a NH DIN 2 type fuse, or, for example, a thickness of a protective body of the fuse may be adapted, i.e. made thinner, such that a ceramic part of the protective body (if any) and an electronics part of a current sensing unit in the protective body together can still comply with a standardized size of, for example, a NH DIN 2 type fuse.

FIG. 3 shows a schematic and enlarged representation of a current sensing unit in the first embodiment of FIG. 1, especially an enlarged view of the shaded part 15 and the sensor 5 in FIG. 1. The current sensing unit 4 can comprise a data memory 6 arranged to store the current sensing unit's measurements, or optionally to store also an identification code. It is preferred that the current sensing unit 4 also includes a control unit, for example a microprocessor 7, configured to control a functioning of the current sensing unit 4. In that case, as shown in FIG. 3, the data memory 6 is communicatively linked with a current sensor via the microprocessor 7. A current measurement (e.g. including or consisting of a non-zero current measurement value), for example via a voltage measurement by the sensor 5, can be transmitted to the microprocessor 7 via an AD convertor. Also an identification code of the current sensing unit 4 can be transmitted to the microprocessor 7 via an AD convertor. The current sensing unit 4 is preferably also configured to transmit, for example upon interrogation by the interrogating device 3, a wireless signal containing measurement results (e.g. including or consisting of one or more non-zero current measurement values) from the current sensing unit 4 to the interrogating device 3, the current sensing unit preferably including a transmitter or transceiver 8 to transmit such information. The transmitter or transceiver 8, which in this embodiment is operably connected with the microprocessor 7, can be configured to function in a receiving and in a transmitting modus. In a receiving modus, it can receive interrogation commands from the interrogating device 3. In a transmitting modus, the transmitter can transmit data via an antenna to the interrogating device 3, e.g. at an adaptive rate, depending on the transmission technology and the circumstances. Interrogation commands received by the transmitter or transceiver 8 can include types of measurements to be transmitted, for example instantaneous current measurements results, or for example mean current measurements over a given period of time. Alternatively, in a most basic embodiment, the transmitter 8 can be configured to operate in a “fire and forget” mode to transmit measurement results, optionally together with an identification code, to the interrogating device 3 without being interrogated by the device 3.

In an advantageous embodiment, the transmitter or transceiver 8 may include RFID transmission means, for example a sensor enabled RFID tag, and the interrogating device 3 may be configured to wirelessly interrogate the RFID transmission means of the current sensing unit 4. The sensor enabled RFID tag may be configured to operate in the passive mode, which does not need power supply and only transmits as an answer to an interrogating signal. The sensor enabled RFID tag may also be configured to operate in a semi-passive or active mode requiring a power supply, for example a battery 9. The RFID tag may include the aforementioned identification code. The RFID system can operate for example in the class 1 generation 2 mode UHF band around 868 Mhz. In this way, the system can bridge a distance between the transmitter and the interrogating device of for example 5 m or more.

In a preferred embodiment, the current sensing unit 4 may comprise an energy harvesting means, for example a coil, replacing a battery or a supercapacitor 9, arranged to provide the current sensing unit 4 with energy to operate. An energy harvesting coil can advantageously be installed near an inner side of the protective body 2 of the fuse 1. The coil can make use of an induced magnetic field generated by, for example, a current in the fuse. Alternatively, the voltage drop over the fuse's resistor could, for example in combination with a transformer, be used to provide voltage to the current sensing unit. Optionally, the current sensing unit 4 can also comprise a timer 10, which is operatively connected with the microprocessor 7.

During use, electric current in a network comprising a system as schematically illustrated in the Figures, can be efficiently monitored so that possible problems in a network can be prevented before they might occur. A current can be determined in the electric fuse, for example via a voltage drop measurement across a fusible resistor in the electric fuse 1, for example at regular intervals. Current determinations from the current sensing unit 4 can be transmitted, for example together with an RFID code, to an interrogating device 3, where received data from the at least one current sensing unit can be processed.

FIG. 4 shows a schematic representation of a second embodiment of a system according to the invention. The system further comprises a central management device 11, e.g. a server, computer, computer system or the like, communicatively connected via a communication link 16 to at least one interrogating device 3, in this case to a plurality of interrogating devices 3. The communication link 16 may be a wireless communication link 16 or a wired link, for example a glass fibre or copper-wired link. Each of the plurality of interrogating devices 3 may be located in one of a plurality of distribution transforming end stations 12 of an electric power distribution network, or one of a plurality of main switch rooms, for example switch rooms of large buildings or industrial plants, in each of which can be installed a plurality of electrical fuses 1 according to the invention and at least one interrogating device 3 per distribution transforming end station or per main switch room. In each distribution transforming end station 12 or main switch room the communication between a fuse's 1 current sensing unit 4 and the interrogating device 3 can be effected via RFID communication as described above. Each interrogating device 3 can also be equipped with a modem 13 configured to communicate with the central management device 11, which is arranged to store and process data received from the at least one interrogating device 3. This communication can for example be effected wirelessly, for example via Code Division Multiple Access (CDMA) communication, or otherwise. In each distribution transforming end station 12 or main switch room the system may also comprise a data aggregator or concentrator device connected to the interrogating device 3 and arranged to collect and temporarily store measurement results received via the interrogating device 3 from the current sensing unit 4 until these results have been transmitted to the central management device 11, for example once a day or more or less often. The communication link may then also be configured to immediately transmit measurement results, for example in combination with an alarm signal, to the central management device 11 if they exceed predetermined values. In this way, it becomes possible to monitor the electric current, and the status of a low voltage network, at any moment, thus providing useful information for the optimization of the network, for example a detection of a possible bottleneck in the network. This information can then be used to optimize the network in a pro-active way, preventing problems rather than solving them when they occur.

FIG. 5 shows a schematic representation of part of an electric power distribution network according to an aspect of the invention. The network, for example extending in a city or a country, may comprise a main electric power station P, from which electric power can be transported via high or medium voltage power transmission cables H to a plurality of distribution transforming end stations 12. These end stations 12 are preferably located near customers' premises E and arranged to transform a voltage from a transmission voltage, for example high or medium voltage, to a voltage adapted for household appliances, for example a low voltage of circa 110, 220 or 230 V. The end stations 12 are connected to end users E via low voltage power transmission cables L, adapted for one- or three-phase electric power transmission. Each of the plurality of distribution transforming end stations 12 can then equipped with a system according to the invention and/or as schematically shown in FIG. 4. In case of three-phase electric power transmission, it can for example be very advantageous to install three electrical fuses 1 per three-phase power distribution cable, one for each phase, so that current can be sensed per cable.

For a still more complete monitoring system, other sensing units or non-sensing assets, in a distribution transforming end station or in a main switch room, for example an air temperature or humidity sensing unit, or an transformer's oil temperature sensing unit, one or more voltages sensors, or a transformer, could also be equipped with an RFID tag, so as to complete the electric current monitoring system with relevant additional network information, for example the positioning and identification of every individual element within a network. The RFID tag can comprise a unique identification code. Preferably, that code is transmitted upon interrogation and, for example, processed centrally to identify every individual element within a network. Also, the monitoring system can include one or more RFID-tag readers for reading RFID-tags. Such tags can be provided on one or more components of the electricity distribution network, for example on a number of network components that are located within a housing of a network distribution transformer end station or within a housing of a main switch room.

It should be clear to the person skilled in the art that the invention is not limited to the embodiments described above. Many alternatives are possible within the scope of protection as formulated in the claims hereafter. As mentioned above, the fuse can for example take any standardized form of a fuse. The system could also be adapted for the monitoring of networks other than low voltage networks. Other wireless communication protocols for the communication between the current sensing unit and the interrogating device could for example also be integrated into the system. Communication within the monitoring system can for example also make use of internet communication or powerline communication.

Also, as follows from the above, the current monitoring is particularly carried out during a normal network operation (that is, in case the respective one or more fuses conduct respective current/currents that is/are monitored or measured by respective current sensing unit/units).

1. A system for monitoring electric current in a network comprising:
at least one electrical fuse including a protective body, and
at least one interrogating device arranged to interrogate at least one current sensing unit,
wherein the at least one current sensing unit is integrated within the protective body of the fuse.

2. The system according to claim 1, wherein the at least one current sensing unit is arranged to deduce a current measurement from a sensing of a current induced magnetic field.

3. The system according to claim 2, wherein the at least one current sensing unit comprises a Rogowski coil or a Hall effect sensor.

4. The system according to claim 1, wherein the at least one current sensing unit comprises a sensor arranged to measure a voltage drop across a resistor, wherein the resistor across which a voltage drop is measured is a fusible element of the at least one electrical fuse.

5. The system according to claim 1, wherein the at least one current sensing unit comprises a data memory arranged to store measurements of the at least one current sensing unit

6. The system according to claim 1, wherein the at least one electrical fuse comprises a data memory to store an identification code.

7. The system according to claim 1, wherein the at least one current sensing unit comprises a control unit, in the form of a microcontroller or a microprocessor, configured to control a functioning of the at least one current sensing unit.

8. The system according to claim 1, wherein the at least one current sensing unit is configured to transmit, upon interrogation by the interrogating device, a wireless signal containing measurement results, or results derived therefrom, from the at least one current sensing unit to the interrogating device, the at least one current sensing unit including a transmitter to transmit such information.

9. The system according to claim 1, wherein the at least one current sensing unit includes RFID transmission means or a sensor enabled RFID tag, and wherein the interrogating device is configured to wirelessly interrogate the RFID transmission means or RFID tag of the at least one current sensing unit.

10. The system according to claim 1, wherein the at least one current sensing unit comprises an energy harvesting coil arranged to provide the at least one current sensing unit with energy to operate.

11. The system according to claim 1, wherein the at least one electrical fuse is a blade type fuse or a standardized NH-type fuse.

12. The system according to claim 1, further comprising a remote central management device communicatively connected via a communication link to the at least one interrogating device, wherein the central management device is arranged to store and process data received from the at least one interrogating device.

13. An electrical fuse including:
a protective body,
a fusible element being configured to provide overcurrent protection, and
a current sensing unit,
wherein the current sensing unit is integrated within the protective body of the fuse.

14. The electrical fuse according to claim 13, wherein the current sensing unit is configured to transmit, upon interrogation by an interrogating device, a wireless signal containing current measurement results, or results derived therefrom, from the current sensing unit to the interrogating device, the current sensing unit including a transmitter to transmit such information.

15. The electrical fuse according to claim 13, wherein the current sensing unit comprises a sensor arranged to measure a voltage drop.

16. The electrical fuse according to claim 13, wherein the current sensing unit comprises a data memory arranged to store measurements of the current sensing unit.

17. The electrical fuse according to claim 13, wherein the current sensing unit comprises a control unit, in the form of a microcontroller or a microprocessor, configured to control the functioning of the current sensing unit.

18. The electrical fuse according to claim 13, comprising RFID transmission means for wireless communication with an RFID interrogating device, including for transmission of an RFID identification code.

19. The electrical fuse according to claim 13, wherein the electrical fuse is a blade type fuse or a standardized NH-type fuse.

20. The electrical fuse according to claim 13, wherein the fuse comprises a data memory to store an identification code and/or to store measurement results or results derived therefrom.

21. A method to monitor electric current in a network using at least one system according to claim 1, the method including the steps of;
determining a current in the at least one via a voltage drop measurement across a fusible resistor in the at least one electrical fuse;
transmitting current determinations from the at least one current sensing unit to a central management device; and
processing received data from the at least one current sensing unit.

22. The method according to claim 21, further including the steps of:
storing said current determination in a data memory of the at least one current sensing unit; and
interrogating wirelessly, the at least one current sensing unit of the at least one electrical fuse.

23. An electric power distribution network comprising at least one distribution transformer end station located near a customer's premise and arranged to transform a voltage from a transmission voltage to a voltage adapted for household appliances, wherein the distribution transformer end station comprises a system according to claim 1.

24. A method to transform an electric power distribution network into a network comprising a system according to claim 1, including the step of: replacing at least one electric fuse in a circuit by using an electrical fuse comprising: a protective body, a current sensing unit integrated within the protective body of the fuse and a fusible element being configured to provide overcurrent protection.
